(19) United States
(12) Patent Application Publication
(10) Pub. No.: US 2005/0257117 A1
(43) Pub. Date: Nov. 17, 2005

(54) METHOD AND CIRCUIT FOR DETERMINING AN ENDING OF AN ETHERNET FRAME

(76) Inventor: Weirong Chiang, Hsin-Chu Hsien (TW)

Correspondence Address: NORTH AMERICA INTELLECTUAL PROPERTY CORPORATION, P.O. BOX 506, MERRIFIELD, VA, 22116, US

(21) Appl. No.: 10/709,526

(22) Filed: May 12, 2004

(51) Int. Cl. G06F 11/00; G01R 31/28; H03M 13/00; G06F 11/10

(52) U.S. Cl. 714/758

(57) ABSTRACT

A method for determining an ending of a frame in serial data is provided. The frame has in sequence a header, a data stream, and a cyclic redundancy check (CRC) corresponding to the data stream. The last bit of the frame is the last bit of the CRC. The method includes (a) detecting the header of the frame, (b) determining the initial bit of the data stream according to the header of the frame, (c) utilizing a generator polynomial corresponding to the CRC of the data stream to perform CRC calculation on the initial bit of the data stream, in order to generate a remainder, and (d) comparing the remainder with a fixed value, wherein the last bit of the plurality of bits is determined to be the ending of the frame when the remainder equals to the fixed value.

### BACKGROUND OF INVENTION

1. Field of the Invention

The present invention relates to a method and a circuit for receiving an Ethernet™ frame, and more specifically, to a method and a circuit for determining an ending of an Ethernet™ frame.

2. Description of the Prior Art

A modern information-oriented society requires networks, which are well developed, so that data and information can be exchanged rapidly over a broad area. An ideal network to deliver information would have low development cost, high quality, and, to address the requirements in increases in bandwidth and the number of users, high speed. Ethernet™ fulfills such kinds of requirements.

For serial transmission, the HDLC (high-level data link control) protocol is generally used to transmit Ethernet™ frames. As known in the industry, the HDLC protocol was developed by the ISO (international organization for standardization) and is applied in a data link layer to perform flow control, error control, and sequence control. An Ethernet frame complying with the HDLC protocol includes at least an initial label, an ending label, a piece of address information, a piece of control information, a data stream to be transmitted, and a frame check sequence (FCS). The initial label is located in the initial 8 bits of the frame, and the ending label is located in the last 8 bits of the frame; that is to say the data stream to be transmitted is located in a frame between the initial label and the ending label. The address information is for recording the addresses of receiving ends or transmitting ends, and the control information is for recording control commands and sequence numbers in order to control the signal transmission between the receiving ends and the transmitting ends.

In addition, the HDLC standard calls for the corresponding FCS to be attached next to the data stream to be transmitted. Commonly, a CRC (e.g. CRC-16 or CRC-32) generated from a cyclic redundancy check (CRC) calculation performed on the data stream to be transmitted is used as the FCS. The FCS serves as a means of validating the integrity of the data stream to be transmitted. Therefore, if a receiving end finds any incorrect bits in the data stream according to the CRC, it will not receive the data stream.

Please refer to FIG. 1 showing a block diagram of a conventional transmitter 10. The transmitter 10 includes an Ethernet interface 12, a control circuit 14, a bit stuffing circuit 16, a CRC generating circuit 18, a memory 20, a parallel-to-serial converter 22, and a data transmitter 24. The Ethernet interface 12 is for receiving input data DATA and dividing it into corresponding frames, the input data DATA being the data stream to be transmitted. The control circuit 14, the bit stuffing circuit 16, and the CRC generating circuit 18 are for packing the input DATA that has been divided into frames and received from the Ethernet interface 12 according to HDLC protocol. The control circuit 14 attaches the initial label, the ending label, the address information, and the control information to the data stream to be transmitted while the CRC generating circuit 18 performs a CRC calculation on the data stream to be transmitted to calculate a CRC, which is then attached it to the data stream to be transmitted. The data stream to be transmitted and its corresponding CRC are then stored in the memory 20.

According to the HDLC standard, the initial label and the ending label are both 8 bits in length of the value “01111110”. The receiving end utilizes the initial label and the ending label to determine the initial byte and the ending byte of a frame complying with HDLC protocol. Therefore, with the exception of the initial label and the ending label, string value of “01111110” in the bit stream should not exist in anywhere in the frame, or else the receiving end will determine incorrectly the initial label and the ending label of the frame. Consequently, to prevent such an error, a bit stuffing circuit 16 is installed in the receiver 10 to stuff bits anywhere into the bit stream other bits except in the initial label and the ending label in the frame. For instance, if a string of bits besides the initial label and the ending label in the frame includes 5 continuous “1”s, such as “0111111111110”, the bit stuffing circuit 16 will insert “0” after the 5 continuous “1”s to change the string into “011111011111010”. Therefore, incorrect determination of the initial label and the ending label can be prevented by stuffing “0” into the data stream.

Subsequently, the parallel-to-serial converter 22 converts the bytes stored in the memory 20 into continuous bits; that is, the parallel-to-serial converter 22 can generate serial data and output them to the data transmitter 24. Finally, the data transmitter 24 converts the serial data to electrical signals or optical signals, and transmits them to the receiving end via a cable or optical fiber.

Please refer to FIG. 2 showing a block diagram of a conventional receiver 30. The receiver 30 includes a data receiver 32, an initial label searching circuit 34, a stuffed bit erasing circuit 36, a memory 38, a CRC generating circuit 40, a comparing circuit 42, a serial-to-parallel converter 44, and an Ethernet interface 46. The data receiver 32 receives the electrical signals or the optical signals output with the transmitter 10 via a cable or optical fiber and then converts them into corresponding serial data for output to the initial label searching circuit 34. The initial label searching circuit 34 is for searching the serial data for an initial label (i.e. “01111110”). When the initial label searching circuit 34 finds an initial label, it is known that the initial label and the continuous bits after it form a frame. Subsequently, the stuffed bit erasing circuit 36 is turned on to erase the “0”s stuffed by the bit stuffing circuit 16. For instance, in the above example, the bit stuffing circuit 16 inserted one “0” after every five “1”s, meaning that the stuffed bit erasing circuit 36 will erase the unnecessary “0”s according to this rule.

After the stuffed bit erasing circuit 36 completes its operation, the remaining bits (including the data stream to be transmitted and the corresponding CRC) will be temporarily stored in the memory 38. The CRC generating circuit 40 will begin performing a CRC calculation on the data stream to be transmitted, outputting the result to the comparing circuit 42. The comparing circuit 42 compares the result with the CRC corresponding to the data stream to be transmitted stored in the memory 38. If the both are the same, the serial data does not include any incorrect bits, meaning that the serial-to-parallel converter 44 is allowed to convert the serial data stored in the memory 38 into corresponding bytes, and then the Ethernet™ interface 46 converts them into data DATA to be received.

As shown in FIG. 1, in the case of packing the frames output by the Ethernet™ interface 12 by means of conventional HDLC protocol, the transmitter 10 requires that a control circuit 14, a bit stuffing circuit 16 and a CRC generating circuit 18 be installed in order to generate frames complying with the HDLC protocol. Therefore, the transmitter 10 is very complicated in structure. Moreover, as shown in FIG. 2, in the case of packing the frames output by the Ethernet™ interface 12 by means of conventional HDLC protocol, the receiver 30 is requires that a stuffed bit erasing circuit 36 be installed in order to erase unnecessary bits, so that the structure of the receiver 30 becomes accordingly complicated. Generally, in order to improve efficiency in the processing of frames, the memories 20, 38 usually used for the transmitter 10 and the receiver 30 are of high capacity so that the frames can be processed in pipelines, which increases cost accordingly. Moreover, for peer-to-peer transmission, the processing of the frames will be inefficient if the transmitter 10 and the receiver 30 utilizes the HDLC protocol to pack the frames.

### SUMMARY OF INVENTION

It is therefore a primary objective of the present invention to provide a method and a circuit for determining an ending of an Ethernet™ frame, in order to solve the problems in the prior art.

Briefly summarized, a method for determining an ending of a frame in serial data is provided. The frame has in sequence a header, a data stream, and a cyclic redundancy check (CRC) corresponding to the data stream. The last bit of the frame is the last bit of the CRC. The method includes (a) detecting the header of the frame, (b) determining an initial bit of the data stream according to the header of the frame, (c) utilizing a generator polynomial corresponding to the CRC of the data stream to perform CRC calculation on the initial bit of the data stream for generating a remainder, and (d) comparing the remainder with a fixed value, wherein the last bit of the bits is determined to be the ending of the frame when the remainder is equal to the fixed value.

The present invention further provides a receiver for receiving a frame. The frame has in sequence a header, a data stream, and a CRC corresponding to the data stream. The last bit of the frame is the last bit of the CRC. The receiver includes a searching circuit for detecting the header of the frame, a CRC generating circuit electrically connected to the searching circuit for determining an initial bit of the data stream according to the header of the frame and performing a CRC calculation on the initial bit of the data stream through a generator polynomial corresponding to the CRC of the data stream to generate a remainder, a comparing circuit electrically connected to the CRC generating circuit for comparing the remainder with a fixed value, and a determining logic circuit electrically connected to the comparing circuit for determining whether the last bit of the bits is the ending of the frame according to the output of the comparing circuit.

The claimed method performs CRC calculation on the data to be transmitted P(x) and the CRC R(x). When the result of calculation equals to the predetermined value, the last bit of the processed serial data is the last bit of the CRC R(x). Therefore, although each frame is different in bit length, the claimed method utilizes the CRC R(x) included in the frame to determine the ending of the frame. Since the frames output by the Ethernet™ interface are not packed according to HDLC protocol, the claimed method does not require a large number of memories and complicated logic circuits to process the frames according to HDLC protocol. To sum up, the claimed invention is more efficient in data processing, and simplified in circuit structure.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a block diagram of a conventional transmitter.

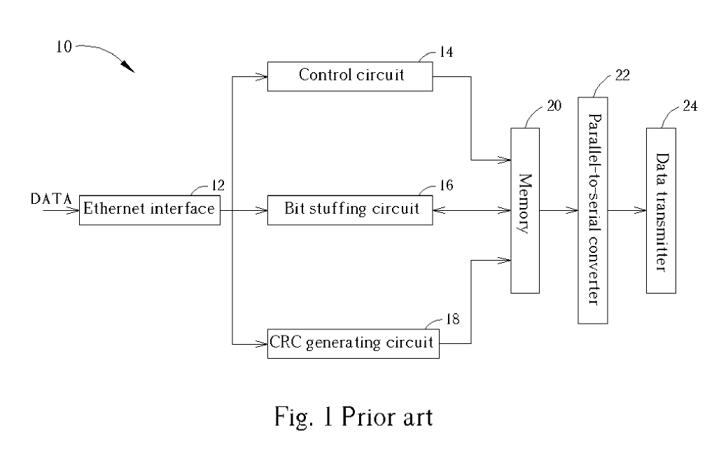

FIG. 2 is a block diagram of a conventional receiver.

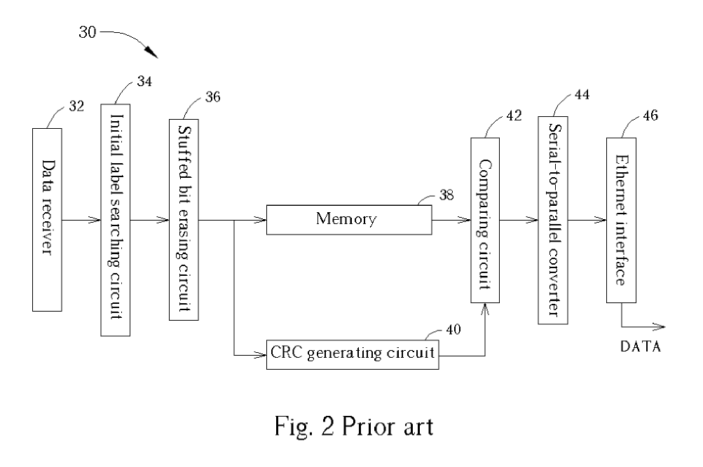

FIG. 3 is a block diagram of a transmitter according to the present invention.

FIG. 4 is a flowchart of determining the ending of the frame according to the present invention.

FIG. 5 is a block diagram of a receiver according to the present invention.

### DETAILED DESCRIPTION

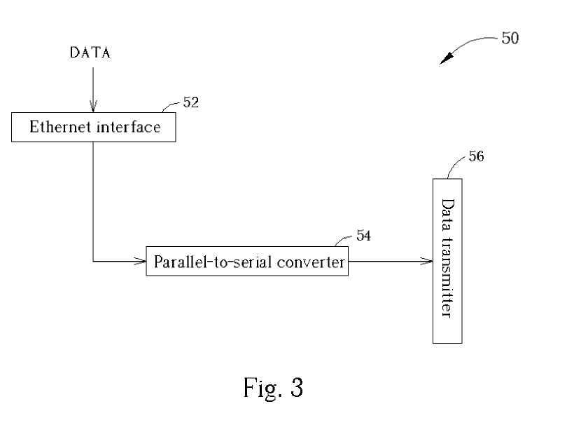

Please refer to FIG. 3 showing a block diagram of a transmitter 50 according to the present invention. The transmitter 50 includes an Ethernet interface 52, a parallel-to-serial converter 54, and a data transmitter 56. The Ethernet interface 52 is for receiving data DATA, converting it into corresponding frames, and outputting the frames to the parallel-to-serial converter 54. The parallel-to-serial converter 54 converts the received bytes into continuous bits (i.e. serial data), and then outputs them to the data transmitter 56. Finally, the data transmitter 56 converts the serial data into corresponding electrical signals or optical signals for output to a receiving end via a cable or optical fiber. As known by the industry, a header of the frame generated by the Ethernet™ interface 52 includes a preamble “0×555A” to serve as an initial label of the frame. Moreover, the frame further includes data to be transmitted (e.g. the data DATA) and a CRC corresponding to the frame. The CRC is attached next to the data to be transmitted and is the ending of the frame. In the present embodiment, the transmitter 50 does not utilize the conventional HDLC protocol to pack the frame when outputting the data DATA. Thus, it is impossible to determine the ending of the frame by using an ending label. Therefore, the present embodiment utilizes the characteristics of the CRC to determine the ending as follows.

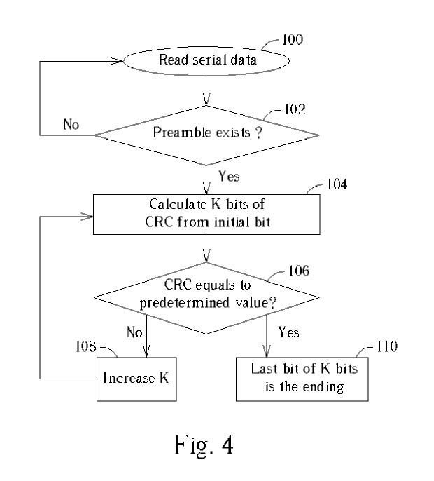

Please refer to FIG. 4 showing a flowchart of determining the ending of the frame according to the present invention. First, read the serial data output by the transmitter 50 (cf. Step100), and then determine whether the serial data includes a plurality of continuous bits corresponding to the preamble “0×555A” according to each bit of the serial data (cf. Step102). It is known that the preamble “0×555A” is used as the header of a frame in order to signal that there is data to be transmitted after the preamble “0×555A.” In other words, if the 16 continuous bits (e.g. B₀-B₁₅) of the serial data do not correspond to the preamble “0×555A” in Step102, re-read another 16 continuous bits (e.g. B₁-B₁₆) of the serial data to determine whether the preamble “0×555A” exists. If the preamble “0×555A” exists, the initial bit of the data to be transmitted P(x) can be known according to conventional frame format. Thus, the present embodiment performs CRC calculation on the bits following the initial bit of the data to be transmitted P(x) in order to generate the CRC (cf. Step 104). For instance, the generator polynomial G(x) used in the CRC calculation is:
x³²+x²⁶+x²³+x²²+x¹⁶+x¹²+x¹¹+x¹⁰+x⁸+x⁷+x⁵+x⁴+x²+x+1

And then, the present embodiment determines whether the CRC is equal to a predetermined value, in order to determine the ending of the frame (cf. Step106). According to the ITU-T V.42 standard, the CRC R(x) transmitted by the frame is a complement of the CRC R(x), and the relationship between the data to be transmitted P(x) and the CRC R(x) is as follows:
P(X)*x³²=M(x)*G(x)+R(x)

That is, the quotient is M(x), and the CRC R(x) is a remainder. As known by the industry, when the Ethernet™ interface 52 performs CRC calculation to the data to be transmitted P(x), it makes the remainder become “0×11111111.” Thus, the relationship between the data to be transmitted P(x) and the CRC R(x) is as follows:
P(x)*x32+0×11111111=M(x)*G(x)+R(x)+0×11111111=M(x)*G(x)+R(x)

Wherein R(x)+0×11111111 is R(x), and the frame generated by the Ethernet™ interface 52 includes the data to be transmitted P(x) and the CRC R(x) instead of the data to be transmitted P(x) and the CRC R(x). Therefore, when performing CRC calculation to all bits of the data to be transmitted P(x) and the CRC R(x) according to the generator polynomial G(x), the CRC obtained is equal to a fixed value 0×DEBB20E3. In other words, the relationship between the generator polynomial G(x), the data to be transmitted P(x), the CRC R(x), and the CRC R(x) is as follows:
P(x)+R(x)=M(x)*G(x)+R(x)+R(x)

Therefore, if the generator polynomial G(x) is used to perform CRC calculation to the data to be transmitted P(x) and the CRC R″(x), then,

$$\begin{matrix}\frac{[ P ( x ) + {R}^{′} ( x ) ] * {x}^{32}}{G ( x )} = M ( x ) * {x}^{32} + \frac{[ R ( x ) + {R}^{′} ( x ) ] * {x}^{32}}{G ( x )} \\ = M ( x ) * {x}^{32} + \frac{0 \times FFFFFFFF00000000}{G ( x )}\end{matrix}$$

That is, the remainder (i.e. the CRC) is 0×C704DD7B. As described above, the CRC R(x) is the last 32 bits of a frame; in other words, the last bit of the CRC R(x) is the last bit of the frame. Therefore, if the CRC obtained from k bits counted from the initial bit of the data to be transmitted P(x) does not equal to the fixed value 0×C704DD7B, the k bits does not include all bits of the data to be transmitted P(x) and the CRC R(x). Therefore for CRC calculation, it is required to process more bits after the initial bit of the data to be transmitted P(x) (cf. Step108), until the CRC equals to the fixed value 0×C704DD7B. In other words, when the CRC obtained equals to the fixed value 0×C704DD7B, the k bits correspond to the data to be transmitted P(x) and the CRC R(x), and the last bit of the k bits is the last bit of the frame. In such a manner, the present embodiment can determine the initial and the ending of a frame.

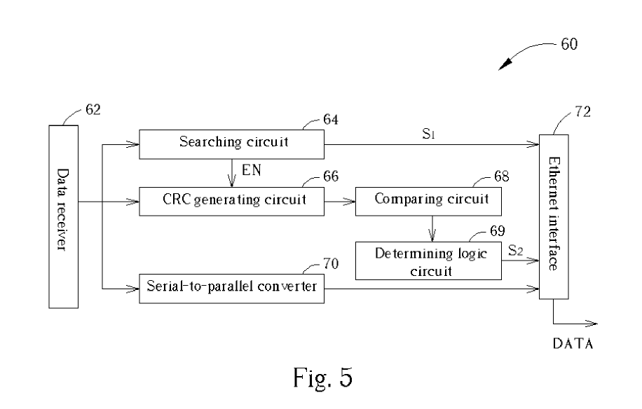

Please refer to FIG. 5 showing a block diagram of a receiver 60 according to the present invention. The receiver 60 includes a data receiver 62, a searching circuit 64, a CRC generating circuit 66, a comparing circuit 68, a determining logic circuit 69, a serial-to-parallel converter 70, and an Ethernet interface 72. The data receiver 62 is for receiving electrical or optical signals output from the receiver 60 through a cable or optical fiber, converting them into corresponding serial data, and then outputting the serial data to the searching circuit 64, the CRC generating circuit 66, and the serial-to-parallel converter 70. In the present invention, the receiver 60 operates according to the flow shown in FIG. 4. The searching circuit 64 searches for a preamble 0×555A corresponding to a frame in the serial data output by the data receiver 32. When detecting the preamble 0×555A, the searching circuit 64 will output a control signal S1 to notify the Ethernet™ interface 72, and an enabling signal EN to the CRC generating circuit 66. Thus, when the CRC generating circuit 66 is triggered by the enabling signal EN, it will start to perform CRC calculation from the initial bit of the data to be transmitted P(x), and output the result of calculation to the comparing circuit 68. The comparing circuit 68 compares the result of calculation with a predetermined value 0×C704DD7B, and outputs the result of comparison to the determining logic circuit 69. If the result of calculation does not equal to the predetermined value 0×C704DD7B, the bits currently processed by the CRC generating circuit 66 do not completely correspond to the data to be transmitted P(x) and the CRC R(x). Thus, the CRC generating circuit 66 continues CRC calculation. On the other hand, when the result of calculation is equal to the predetermined value 0×C704DD7B, the bits currently processed by the CRC generating circuit 66 completely correspond to the data to be transmitted P(x) and the CRC R(x). Thus, the determining logic circuit 69 generates a control signal S2 to notify the Ethernet interface 72. Finally, the Ethernet interface 72 captures the data DATA transmitted in frames by the transmitter 50 from the plurality of received bytes, according to the control signals S1, S2.

As described above, when detecting a preamble 0×555A corresponding to a frame, the searching circuit 64 will output the enabling signal EN to trigger the CRC circuit 66 to perform CRC calculation from the initial bit of the data to be transmitted P(x), and determine the ending of the frame according to the result of calculation. However, if the searching circuit 64 misjudges the heading of the frame, the CRC generating circuit 66 will repeatedly continue CRC calculation because the result is never equal to the predetermined value 0×C704DD7B. In other words, in the transmission path between the transmitter 50 and the receiver 60, the frames may be interfered with, generating incorrect bits so that the searching circuit 64 misjudges the heading of the frame, and the determining logic circuit 69 cannot find the ending of the frame according to the result of comparison. Therefore in the present embodiment, if the searching circuit 64 misjudges the heading of the frame, when the data receiver 62 has received the serial data in predetermined amount (e.g. 1536 bytes), and the result of calculation does not still equal to the required value 0×C704DD7B, the CRC generating circuit 66 will still stop its operation. In this case, the searching circuit 64 will redetect the preamble 0×555A for the next frame, and re-trigger the CRC generating circuit 66 to execute CRC calculation.

In contrast to the prior art, the method according to the present invention is to perform CRC calculation on the data to be transmitted P(x) and the CRC R(x). When the result of calculation equals to the predetermined value, the last bit of the processed serial data is the last bit of the CRC R(x). Therefore, although each frame is different in bit length, the present invention utilizes the CRC R(x) included in the frame to determine the ending of the frame. Since the frames output by the Ethernet™ interface are not packed according to HDLC protocol, the present invention does not require a large number of memories and complicated logic circuits to process the frames according to HDLC protocol. In other words, the present invention is more efficient in data processing, and simplified in circuit structure.

Those skilled in the art will readily observe that numerous modifications and alterations of the device and the method may be made while retaining the teachings of the invention. Accordingly, the above disclosure should be construed as limited only by the metes and bounds of the appended claims.

1. A method for determining an ending of a frame in serial data, the frame having in sequence a header, a data stream, and a cyclic redundancy check (CRC) corresponding to the data stream with the last bit of the frame being the last bit of the CRC, the method comprising:
(a) detecting the header of the frame;
(b) determining an initial bit of the data stream according to the header of the frame;
(c) utilizing a generator polynomial corresponding to the CRC of the data stream to perform CRC calculation on a plurality of bits beginning with the initial bit of the data stream for generating a remainder; and
(d) comparing the remainder with a fixed value, wherein the last bit of the bits is determined to be the ending of the frame when the remainder is equal to the fixed value.

2. The method of claim 1 wherein the CRC is a complement of the remainder obtained from the CRC calculation performed on the data stream by the generator polynomial.

3. The method of claim 2 wherein the generator polynomial is x³²+x²⁶+x²³+x²²+x¹⁶+x¹²+x¹¹+x¹⁰+x⁸+x⁷+x⁵+x⁴+x²+x+1.

4. The method of claim 3 wherein the fixed value is 0×C704DD7B.

5. The method of claim 1 wherein when the remainder is equal to the fixed value, the bits comprises the data stream and the CRC.

6. The method of claim 1 wherein the header comprises a preamble being 0×555A.

7. The method of claim 1 further comprising:
stopping performing Step(c) when the remainder does not equal to the fixed value and the length of the plurality of bits exceeds a predetermined value.

8. A receiver for receiving a frame, the frame having in sequence a header, a data stream, and a cyclic redundancy check (CRC) corresponding to the data stream with the last bit of the frame being the last bit of the CRC, the receiver comprising:
a searching circuit for detecting the header of the frame;
a CRC generating circuit electrically connected to the searching circuit for determining an initial bit of the data stream according to the header of the frame, and performing CRC calculation to the initial bit of the data stream through a generator polynomial corresponding to the CRC of the data stream to generate a remainder;
a comparing circuit electrically connected to the CRC generating circuit for comparing the remainder with a fixed value; and
a determining logic circuit electrically connected to the comparing circuit for determining whether the last bit of the bits is the ending of the frame according to the output of the comparing circuit.

9. The receiver of claim 8 wherein the CRC is a complement of the remainder obtained from the CRC calculation performed on the data stream by the generator polynomial.

10. The receiver of claim 9 wherein the generator polynomial utilized by the CRC generating circuit is x³²+x²⁶+x²³+x²²+x¹⁶+x¹²+x¹¹+x¹⁰+x⁸+x⁷+x⁵+x⁴+x²+x+1.

11. The receiver of claim 10 wherein the fixed value utilized by the comparing circuit is 0×C704DD7B.

12. The receiver of claim 8 wherein the remainder resulting from the CRC calculation performed by the CRC generating circuit on the data stream and the CRC is equal to the fixed value.

13. The receiver of claim 8 wherein the header comprises a preamble being 0×555A.

14. The receiver of claim 8 wherein when the remainder does not equal to the fixed value, and the length of the plurality of bits exceeds a predetermined value, the CRC generating circuit stops the CRC calculation.

15. The receiver of claim 8 applied in peer-to-peer transmission.
